(19) United States
(12) Patent Application Publication
(10) Pub. No.: US 2012/0248586 A1
(43) Pub. Date: Oct. 4, 2012

(54) SEMICONDUCTOR APPARATUS FOR PREVENTING CROSSTALK BETWEEN SIGNAL LINES

(75) Inventors: Jun Ho LEE, Icheon-si (KR); Hyun Seok KIM, Icheon-si (KR); Boo Ho JUNG, Icheon-si (KR); Sun Ki CHO, Icheon-si (KR); Yang Hee KIM, Icheon-si (KR); Young Won KIM, Icheon-si (KR)

(73) Assignee: HYNIX SEMICONDUCTOR INC., Icheon-si (KR)

(21) Appl. No.: 13/219,633

(22) Filed: Aug. 27, 2011

(30) Foreign Application Priority Data
Mar. 28, 2011 (KR) 10-2011-0027581

(51) Int. Cl. H01L 23/58; H01L 23/48

(52) U.S. Cl. 257/659; 257/774; 257/E23.002; 257/E23.011

(57) ABSTRACT

A semiconductor integrated circuit apparatus includes a semiconductor substrate, a plurality of signal lines, and at least one interface member. The signal lines are disposed on the semiconductor substrate. The interface member is disposed in the semiconductor substrate between the adjacent signal lines among the signal lines to pierce the semiconductor substrate.

### CROSS-REFERENCES TO RELATED APPLICATION

The present application claims priority under 35 U.S.C. §119(a) to Korean application number 10-2011-0027581, filed on Mar. 28, 2011 in the Korean Intellectual Property Office, and which is incorporated herein by reference in its entirety.

### BACKGROUND

1. Technical Field

The present invention relates to a semiconductor integrated circuit apparatus, and more particularly, to a semiconductor integrated circuit apparatus including a shielding structure for preventing crosstalk between signal lines.

2. Related Art

As the integration density of semiconductor integrated circuit apparatuses increases, the distance between signal lines decreases. A decrease in the distance between signal lines causes crosstalk due to coupling noise between the signal lines, thus making it difficult to transmit an accurate signal.

A method of forming a shielding line for preventing crosstalk between adjacent signal lines has been proposed to reduce crosstalk between adjacent signal lines.

However, since the conventional shielding line is disposed on the same plane as the signal lines, it can prevent crosstalk on the same plane but cannot prevent crosstalk with adjacent planes.

### SUMMARY

A semiconductor integrated circuit apparatus for preventing crosstalk between signal lines is described herein.

In one embodiment of the present invention, a semiconductor integrated circuit apparatus includes a semiconductor substrate, a plurality of signal lines disposed on the semiconductor substrate, and at least one interface member disposed to pierce the semiconductor substrate between adjacent signal lines.

In another embodiment of the present invention, a semiconductor integrated circuit apparatus includes a pair of signal lines disposed on a semiconductor substrate, a shielding line disposed on the semiconductor substrate between the pair of signal lines, at least one through-silicon via (TSV) disposed in the semiconductor substrate to electrically contact the shielding line, and a dielectric layer disposed between a sidewall of the TSV and the semiconductor substrate.

In another embodiment of the present invention, a semiconductor integrated circuit apparatus includes a pair of signal lines disposed on a semiconductor substrate, an impurity region disposed in the semiconductor substrate to receive a ground voltage, at least one through-silicon via (TSV) disposed to pierce the semiconductor substrate, and a dielectric layer disposed between a sidewall of the TSV and the semiconductor substrate, wherein the TSV electrically contacts the impurity region.

In another embodiment of the present invention, a semiconductor integrated circuit apparatus includes a stack of semiconductor chips. Each semiconductor chips includes a conductive line and a plurality of signal lines, and at least one through-silicon via (TSV) disposed between adjacent signal lines. The TSV of an upper semiconductor chip in the stack of semiconductor chips is electrically connected to the conductive line of a lower semiconductor chip.

### BRIEF DESCRIPTION OF THE DRAWINGS

Features, aspects, and embodiments are described in conjunction with the attached drawings, in which:

FIG. 1 is a cross-sectional view of a semiconductor integrated circuit apparatus according to an exemplary embodiment of the present invention;

FIG. 2 is a plan view of a semiconductor integrated circuit apparatus according to another exemplary embodiment of the present invention;

FIG. 3 is a cross-sectional view taken along a line III-III′ of FIG. 2;

FIG. 4 is a plan view of a semiconductor integrated circuit apparatus according to another exemplary embodiment of the present invention;

FIG. 5 is a cross-sectional view of a semiconductor integrated circuit apparatus according to another exemplary embodiment of the present invention; and

FIGS. 6 and 7 are plan views of semiconductor integrated circuit apparatuses according to other exemplary embodiments of the present invention.

### DETAILED DESCRIPTION

Hereinafter, a semiconductor integrated circuit apparatus for preventing crosstalk between signal lines according to various exemplary embodiments of the present invention will be described below with reference to the accompanying drawings.

Advantages and features of the present invention, and implementation methods thereof will be clarified through the following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the specification and drawings, like reference numerals denote like elements.

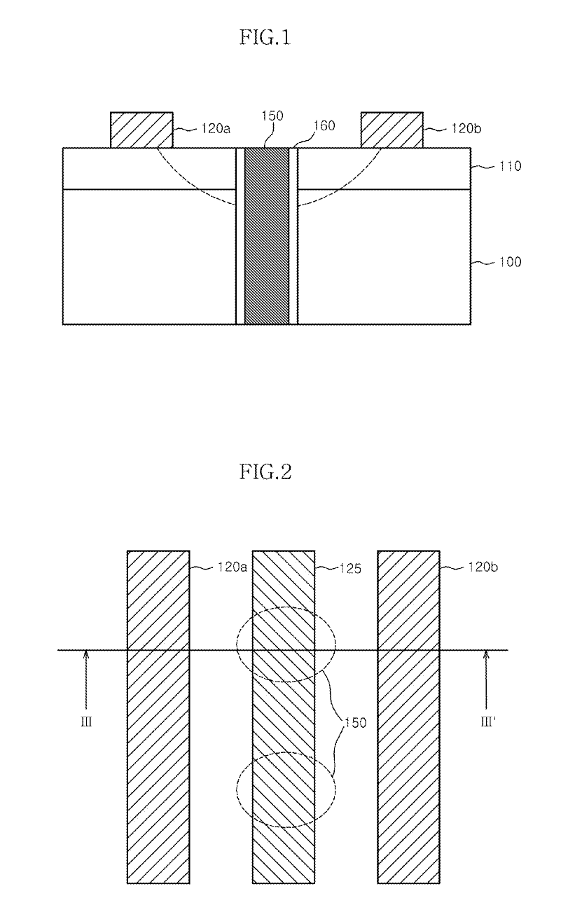

FIG. 1 is a cross-sectional view of a semiconductor integrated circuit apparatus according to an exemplary embodiment of the present invention.

Referring to FIG. 1, a pair of adjacent signal lines 120a and 120b are disposed on a semiconductor substrate 100. An interlayer dielectric 110 is disposed between the semiconductor substrate 100 and the signal lines 120a and 120b. In order to reduce the crosstalk between the signal lines 120a and 120b, an interface member such as a through-silicon via (TSV) 150 is formed in the semiconductor substrate 100 between the signal lines 120a and 120b to pierce the semiconductor substrate 100. As is well known in the art, the TSV 150 is a medium that is formed to connect semiconductor chips by forming a through hole piercing the semiconductor substrate 100 (i.e., a semiconductor chip) and filling the through hole with a conductive material. The sidewall of the TSV 150 is coated with a dielectric layer 160 to insulate the TSV 150 from the semiconductor substrate 100. In FIG. 1, a dotted line represents the interruption of coupling noise between the signal lines 120a and 120b by the TSV 150.

As described above, the TSV 150 is formed in the semiconductor substrate 100 between the adjacent signal lines 120a and 120b, thus preventing crosstalk such as a coupling between the signal lines 120a and 120b that may occur in the semiconductor substrate 100. Herein, the TSV 150 may be in a floating state, without connecting with any conductive line.

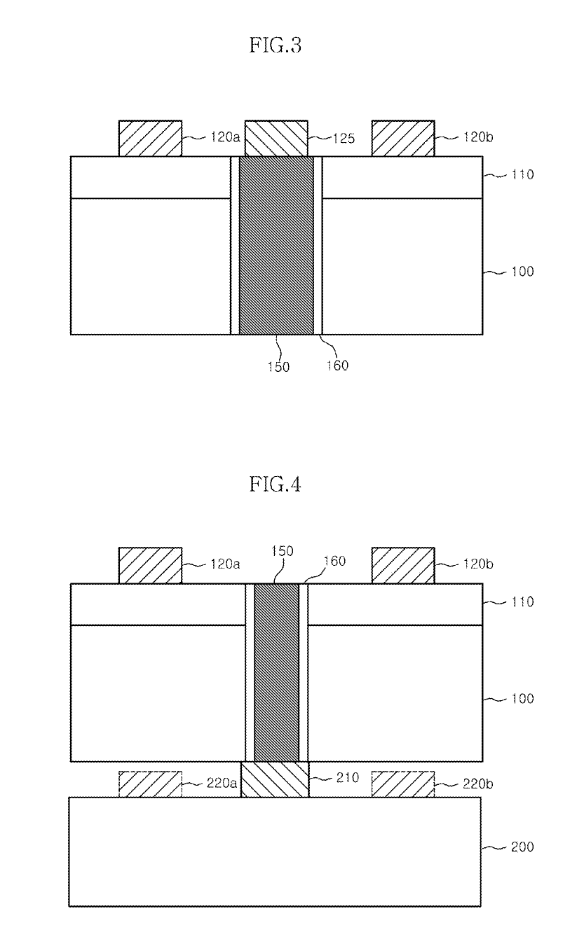

FIGS. 2 and 3 are views illustrating a semiconductor integrated circuit apparatus including a shielding line structure according to another exemplary embodiment of the present invention.

Referring to FIGS. 2 and 3, an interlayer dielectric 110 is disposed on a semiconductor substrate 100. A pair of signal lines 120a and 120b is disposed on the interlayer dielectric 110 such that they are spaced apart from each other by a predetermined distance. A shielding line 125 is disposed between the signal lines 120a and 120b. The shielding line 125 may maintain the same distance from each of the signal lines 120a and 120b. For example, the shielding line 125 may be a ground line or a power line. The shielding line 125 may prevent crosstalk between the signal lines 120a and 120b that may occur on the semiconductor substrate 100.

A TSV 150 is disposed in the semiconductor substrate 100 under the shielding line 125 to contact the bottom of the shielding line 125. The TSV 150 is electrically connected to the shielding line 125 to prevent crosstalk between the signal lines 120a and 120b that may occur in the semiconductor substrate 100. The sidewall of the TSV 150 is coated with a dielectric layer 160 to insulate the TSV 150 from the semiconductor substrate 100.

According to this embodiment, the shielding line 125 is disposed between the signal lines 120a and 120b, and the TSV 150 is disposed in the semiconductor substrate 100 to contact the shielding line 125. Accordingly, it is possible to prevent not only crosstalk between the top portions and the side portions of the signal lines 120a and 120b on the semiconductor substrate 100, but also a noise coupling that may occur between the bottom portions of the signal lines 120a and 120b in the semiconductor substrate 100.

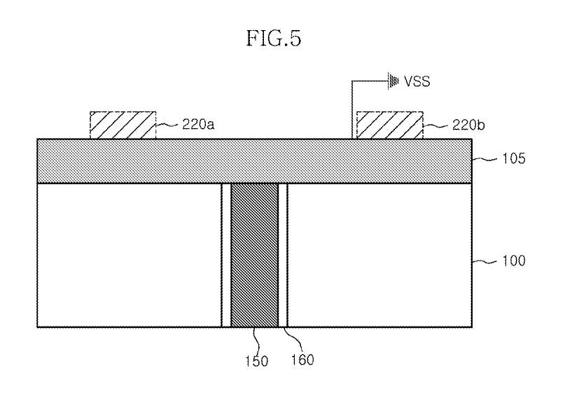

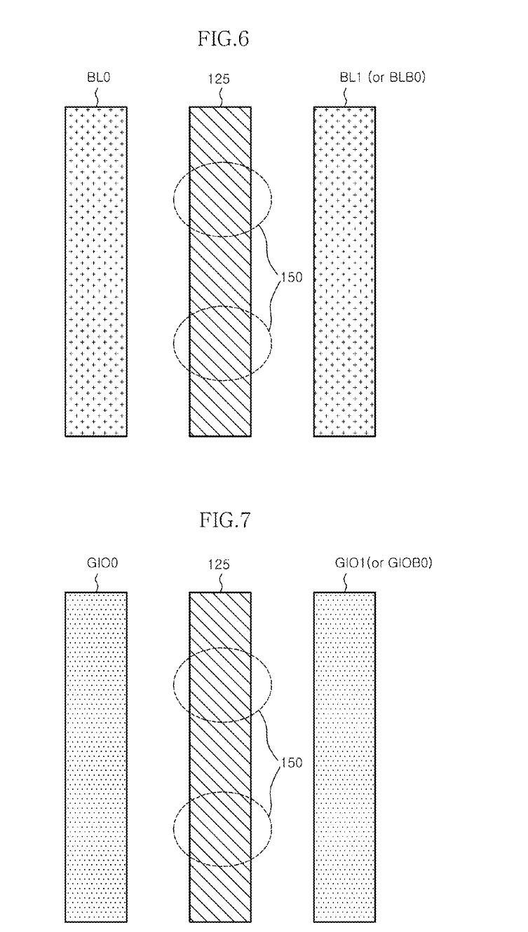

FIG. 4 is a plan view of a semiconductor integrated circuit apparatus according to another exemplary embodiment of the present invention. FIG. 5 is a cross-sectional view of a semiconductor integrated circuit apparatus according to another exemplary embodiment of the present invention. FIGS. 6 and 7 are plan views of semiconductor integrated circuit apparatuses according to other exemplary embodiments of the present invention.

As illustrated in FIG. 4, the TSV 150 may be electrically connected to a conductive line 210 of a semiconductor substrate 200 that may be attached to the bottom thereof (hereinafter referred to as a lower semiconductor chip). Even though a shielding line is not disposed on the semiconductor substrate 100, the TSV 150 is connected to the conductive line 210 of the lower semiconductor chip 200 to prevent crosstalk between the signal lines 120a and 120b. Although the TSV 150 and the conductive line 210 of the lower semiconductor chip 200 are illustrated as being connected directly to each other, the TSV 150 and the conductive line 210 of the lower semiconductor chip 200 may also be connected indirectly to each other.

As described above, the TSV 150 is electrically connected to the conductive line 210 of the lower semiconductor chip 200, thereby making it possible to prevent not only crosstalk between the signal lines 120a and 120b on the semiconductor substrate 100, but also crosstalk between signal lines 220a and 220b on the lower semiconductor chip 200.

Referring to FIG. 5, the TSV 150 may be connected to a well or junction region 105 to receive a ground voltage VSS. Accordingly, it is possible to effectively prevent crosstalk that may occur between the adjacent signal lines 120a and 120b.

The signal lines 120a and 120b may be adjacent bit lines BL0 and BL1 or BL0 and BLB0 as illustrated in FIG. 6, or may be global input/output lines GIO0 and GIO1 or GIO0 and GIOB0 as illustrated in FIG. 7. However, the present invention is not limited thereto, and the signal lines 120a and 120b may be any other signal lines that are adjacent to each other and transmit different signals.

As described above, the shielding line and the TSV contacting the bottom of the shielding line are disposed in at least one place between the adjacent signal lines. Accordingly, it is possible to prevent crosstalk such as a coupling between the adjacent signal lines and a noise coupling that may occur in the semiconductor substrate.

While certain embodiments have been described above, it will be understood to those skilled in the art that the embodiments described are by way of example only. Accordingly, the semiconductor integrated circuit apparatus described herein should not be limited based on the described embodiments. Rather, the semiconductor integrated circuit apparatus described herein should only be limited in light of the claims that follow when taken in conjunction with the above description and accompanying drawings.

What is claimed is:

1. A semiconductor apparatus comprising:
a semiconductor substrate;
a plurality of signal lines disposed on the semiconductor substrate; and
at least one interface member disposed to pierce the semiconductor substrate between adjacent signal lines among the plurality of signal lines.

2. The semiconductor apparatus according to claim 1, further comprising a shielding line disposed between the adjacent signal lines to contact a top portion of the interface member.

3. The semiconductor apparatus according to claim 2, wherein the shielding line is a ground line or a power line.

4. The semiconductor apparatus according to claim 1, wherein the interface member is electrically connected to a conductive line of a lower semiconductor chip attached to a bottom portion of the semiconductor substrate.

5. The semiconductor apparatus according to claim 4, wherein the conductive line is a ground line or a power line.

6. The semiconductor apparatus according to claim 1, wherein
the semiconductor substrate comprises a well or junction region to receive a ground voltage, and
the interface member is electrically connected to the well or junction region.

7. The semiconductor apparatus according to claim 1, further comprising a dielectric layer disposed between a side wall of the interface member and the semiconductor substrate.

8. The semiconductor apparatus according to claim 1, wherein the plurality of signal lines comprise a plurality of bit lines.

9. The semiconductor apparatus according to claim 1, wherein the plurality of signal lines comprise a plurality of input/output lines.

10. The semiconductor apparatus according to claim 1, further comprising an interlayer dielectric disposed between the semiconductor substrate and the plurality of signal lines.

11. A semiconductor apparatus comprising:
a pair of signal lines disposed on a semiconductor substrate;
a shielding line disposed on the semiconductor substrate between the pair of signal lines;
at least one through-silicon via (TSV) disposed in the semiconductor substrate and electrically coupled to the shielding line; and
a dielectric layer disposed between a sidewall of the TSV and the semiconductor substrate.

12. The semiconductor apparatus according to claim 11, wherein the shielding line is a ground line or a power line.

13. The semiconductor apparatus according to claim 11, further comprising an interlayer dielectric disposed between the semiconductor substrate and the pair of signal lines.

14. A semiconductor apparatus comprising:
a pair of signal lines disposed on a semiconductor substrate;
a region disposed in the semiconductor substrate to receive a ground voltage;
at least one through-silicon via (TSV) disposed to pierce the semiconductor substrate; and
a dielectric layer disposed between a sidewall of the TSV and the semiconductor substrate,
wherein the TSV electrically contacts the region.

15. The semiconductor apparatus according to claim 14, wherein the region is a well region or a junction region.

16. A semiconductor apparatus comprising: a stack of semiconductor chips each comprising:
a conductive line and a plurality of signal lines; and
at least one through-silicon via (TSV) disposed between the plurality of signal lines; and
the TSV of an upper semiconductor chip in the stack of semiconductor chips electrically connected to the conductive line of a lower semiconductor chip.
